(19) United States
(12) Patent Application Publication
(10) Pub. No.: US 2024/0431095 A1
(43) Pub. Date: Dec. 26, 2024

(54) SEMICONDUCTOR DEVICE WITH LINED CAPACITOR AND METHODS FOR MANUFACTURING THE SAME

(71) Applicant: Micron Technology, Inc., Boise, ID (US)

(72) Inventors: Yoshitaka Nakamura, Boise, ID (US); Ashwin Panday, Boise, ID (US); Iche Huang, Boise, ID (US); Richard Beeler, Boise, ID (US); Dojun Kim, Boise, ID (US); Lane T. Cunningham, Meridian, ID (US); Adriel Jebin Jacob Jebaraj, Boise, ID (US); Scott E. Sills, Boise, ID (US)

(21) Appl. No.: 18/733,586

(22) Filed: Jun. 4, 2024

Related U.S. Application Data
(60) Provisional application No. 63/523,280, filed on Jun. 26, 2023.

(51) Int. Cl. H10B 12/00

(52) U.S. Cl. CPC H10B 12/30; H10B 12/03

(57) ABSTRACT

Methods, apparatuses, and systems related to a three-dimensional semiconductor device having a doped liner at least disposed between a capacitor and an access device. The doped liner may be configured to provide dopants that diffuse into a semiconductor path of the access device and improve an electrical connection between the access device and the capacitor.

### CROSS-REFERENCE TO RELATED APPLICATION(S)

The present application claims priority to U.S. Provisional Patent Application No. 63/523,280, filed Jun. 26, 2023, the disclosure of which is incorporated herein by reference in its entirety.

### TECHNICAL FIELD

The disclosed embodiments relate to devices, and, in particular, to semiconductor devices with capacitors attached to or through doped liners and methods for manufacturing the same.

### BACKGROUND

A semiconductor device can include one or more circuits, such as a combination of connected transistors, capacitors, and other similar circuit components, fabricated or embedded in semiconductor material. Some examples of the semiconductor device can include a semiconductor die, a package, a system-on-chip, a circuit card, or the like including the semiconductor-based circuits. Such semiconductor device can be configured for a variety of functions, as for a processor or a memory device (e.g., a volatile memory device, a non-volatile memory device, or a combination device).

With technological growth and increasing applications, the market is continuously looking for faster, more efficient, and smaller devices. To meet the market demand, the semiconductor devices are being pushed to the limit with various improvements. Improving devices, generally, may include increasing circuit density, reducing the circuit footprint, increasing operating speeds or otherwise reducing operational latency, increasing reliability, reducing power consumption, or reducing manufacturing costs, among other metrics. For example, three-dimensional (3D) architectures are being researched for semiconductor device designs.

### BRIEF DESCRIPTION OF THE DRAWINGS

FIG. 1 is a block diagram of an apparatus in accordance with an embodiment of the present technology.

FIG. 2 is a perspective cut-out view of an example 3D semiconductor device having a capacitor with a doped liner in accordance with an embodiment of the present technology.

FIG. 3A is a detailed illustration of section 3A of FIG. 2 showing a front view of capacitor structures in accordance with an embodiment of the present technology.

FIG. 3B is a detailed illustration of section 3B of FIG. 2 showing a side view of capacitor structures in accordance with an embodiment of the present technology.

FIG. 4-FIG. 13 and FIG. 15 illustrate example stages in manufacturing the example 3D semiconductor device in accordance with an embodiment of the present technology.

FIG. 14A-FIG. 14C are detailed views of structures shown in FIG. 12 and FIG. 13 in accordance with an embodiment of the present technology.

FIG. 16A is a detailed view of a first example capacitor configuration in accordance with an embodiment of the present technology.

FIG. 16B is a detailed view of a second example capacitor configuration in accordance with an embodiment of the present technology.

FIG. 17 is a flow diagram illustrating an example method of manufacturing a semiconductor device having a capacitor with a doped liner in accordance with an embodiment of the present technology.

FIG. 18 is a schematic view of a system that includes a semiconductor device in accordance with an embodiment of the present technology.

### DETAILED DESCRIPTION

As described in greater detail below, the technology described herein relates to a semiconductor device having a lined capacitor, such as for memory systems, systems with memory devices, etc., and related methods. The semiconductor device can have a 3D architecture that includes capacitors configured to hold charges, such as for representing of stored data. In some embodiments, the capacitors can include double-sided capacitors having a doped liner for providing lower resistance contacts between the capacitors and the access devices (e.g., a data access path provided by the corresponding silicon (Si) transistor) for the 3D architecture. For example, the doped liner can include poly-Si liners with n+ dopants.

In manufacturing the semiconductor device having the 3D architecture (3D device), the cell-contact junction requires an implantation process that is different than ones used for manufacturing two-dimensional devices. Different means of sourcing dopants may be required to form the cell contact junctions.

Embodiments of the present technology can include the doped liner (e.g., the n+ poly-Si liner) within the cell capacitor structure to provide the dopants to the cell contact junctions. The dopants may be diffused from the doped liner into the underlap extension region of the access device and activated. Accordingly, the doped liner can further reduce the capacitor area loss by selectively removing the Si from portions (e.g., top and bottom)_of the cell electrode, thereby enabling double-sided capacitors with the doped liner remaining in place. The doped liner can remain on the remaining portions (e.g., orthogonal sides, such as left and right sides) of the cell electrode, thereby anchoring the capacitor structure to deep trench isolation (DTI) and reducing/avoiding formation of free-standing electrodes (e.g., capacitor bottom electrodes) that are structurally unstable. Additionally, the reduction in the resistance between the capacitors and the access device (e.g., the corresponding Si structure) can provide increased operational speeds while preserving the overall yield during manufacturing.

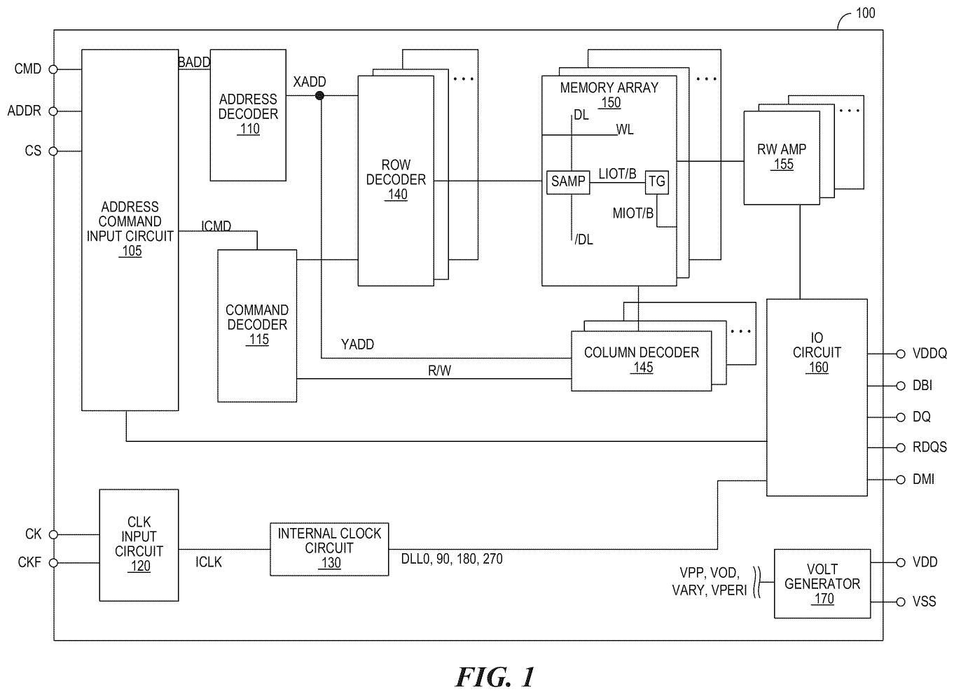

FIG. 1 is a block diagram of an apparatus 100 (e.g., a semiconductor die assembly, including a three-dimensional integration (3DI) device or a die-stacked package) in accordance with an embodiment of the present technology. For example, the apparatus 100 can include a DRAM or a portion thereof that includes one or more dies/chips.

The apparatus 100 may include an array of memory cells, such as memory array 150. The memory array 150 may include a plurality of banks (e.g., banks 0-15), and each bank may include a plurality of WLs, a plurality of DLs, and a plurality of memory cells arranged at intersections of the word-lines and the bit lines. Memory cells can include any one of a number of different memory media types, including capacitive, magnetoresistive, ferroelectric, phase change, or the like. Details regarding the structure of the WLs, the DLs, and the memory cells are described below.

The selection of a word-line WL may be performed by a row decoder 140, and the selection of a digit-line DL may be performed by a column decoder 145. Sense amplifiers (SAMP) may be provided for coupled digit-line DL and connected to at least one respective local I/O line pair (LIOT/B), which may in turn be coupled to at least respective one main I/O line pair (MIOT/B), via transfer gates (TG), which can function as switches. The sense amplifiers and transfer gates may be operated based on control signals from decoder circuitry, which may include the command decoder 115, the row decoders 140, the column decoders 145, any control circuitry of the memory array 150, or any combination thereof. The memory array 150 may also include plate lines and related circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, DMI, power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address (CA) input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded, and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word-line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register. The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials V_{DD} and V_{SS}. These power supply potentials V_{DD} and V_{SS} can be supplied to an internal voltage generator circuit 170. The internal voltage generator circuit 170 can generate various internal potentials Vₚₚ, V_{OD}, V_{ARY}, V_{PERI}, and the like based on the power supply potentials V_{DD} and V_{SS}. The internal potential V_{PP} can be used in the row decoder 140, the internal potentials V_{OD} and V_{ARY} can be used in the sense amplifiers included in the memory array 150, and the internal potential V_{PERI} can be used in many other circuit blocks.

The power supply terminal may also be supplied with power supply potential V_{DD}Q. The power supply potential V_{DD}Q can be supplied to the input/output circuit 160 together with the power supply potential V_{SS}. The power supply potential V_{DD}Q can be the same potential as the power supply potential V_{SS} in an embodiment of the present technology. The power supply potential V_{DD}Q can be a different potential from the power supply potential V_{DD} in another embodiment of the present technology. However, the dedicated power supply potential V_{DD}Q can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1) from the command/address input circuit 105. For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The IO clock signals can be supplied to the input/output circuit 160 and can be used as timing signals for determining output timing of read data and/or input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to the internal clock circuit 130 and thus various internal clock signals can be generated.

The apparatus 100 can be connected to any one of a number of electronic devices capable of utilizing memory for the temporary or persistent storage of information, or a component thereof. For example, a host device of apparatus 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100; although in other embodiments, the host device may be indirectly connected to memory device (e.g., over a networked connection or through intermediary devices).

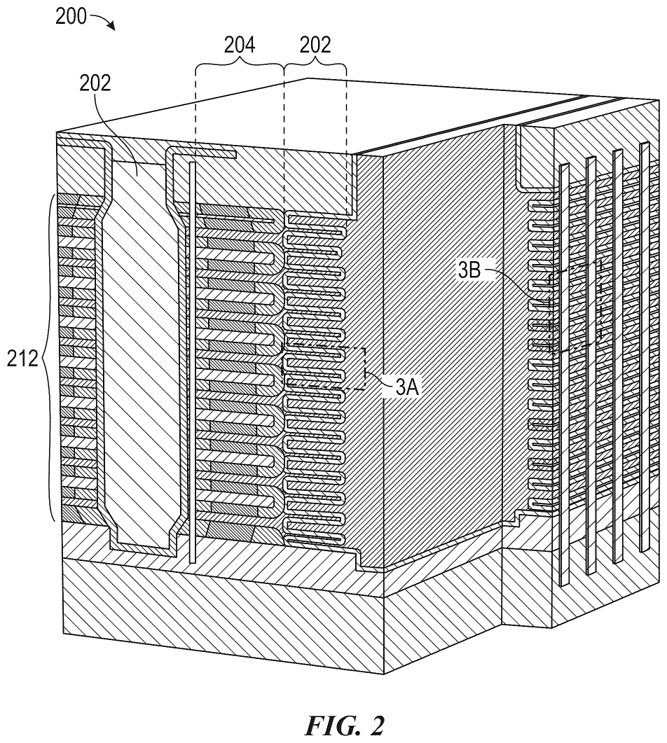

FIG. 2 is a perspective cut-out view of an example 3D semiconductor device 200 (e.g., the apparatus 100 of FIG. 1 or a portion thereof, such as the memory array 150 of FIG. 1) having capacitors 202 with doped liners. The capacitors 202 can be electrically coupled to access devices 214 (e.g., transistors) configured to selectively provide connections to/from the capacitors 202.

Using the apparatus 100 as an example, the capacitors 202 can function as data storage devices or memory cells. Each of the capacitors 202 can include the memory cells that are configured to have multiple states, such as for charge storage, magnetic or resistive state, or the like, that represent stored data (e.g., ‘0’, ‘1’, or a combination thereof). The access devices 214 can include circuits, such as transistors, configured to provide electrical paths, control states of, or both for the coupled one of the capacitors 202. For example, the access devices 214 can be used to write to (by, e.g., controlling the amounts of charges stored therein) the coupled one of the capacitors 202, read from (by, e.g., detecting stored charge levels) the coupled one of the capacitors 202, or both.

In some embodiments, the device 200 can have the capacitors 202 and the coupled access devices 214 arranged in stacked layers 212. The capacitors 202 can be located such that they are arranged (1) laterally across a layer, (2) vertically across layers (e.g., along one or more columns), or a combination thereof. Thus, the access devices 214 can be arranged both laterally and vertically (e.g., along columns). In one or more embodiments, the device 200 can include body contacts that extend vertically across the layers and connect the vertically aligned access devices 214 to provide the transistor body connection.

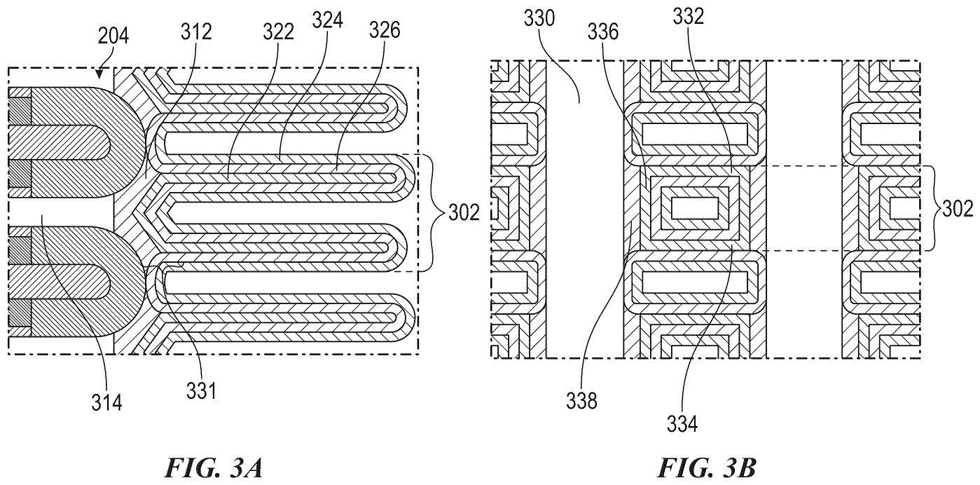

To further describe the connection between the capacitors 202 and the access devices 214, FIG. 3A is detailed illustration of section 3A of FIG. 2 showing a front view of capacitor structures (e.g., the capacitors 202 of FIG. 2), and 3B is a detailed illustration of section 3B of FIG. 2 showing a side view of capacitor structures, both in accordance with an embodiment of the present technology. Referring now to FIG. 3A and FIG. 3B together, the capacitor structures can include a double-sided capacitor 302 coupled to one instance of the access device 204. The double-sided capacitor 302 can include a doped liner 312 (e.g., n+ poly-Si) disposed between a semiconductor path 314 (e.g., a transistor terminal) of the access device. In some embodiments, the doped liner 312 can include phosphine-doped Si, and the semiconductor path 314 can include Si. For example, the semiconductor path 314 can include a source or a drain portion of the access device 204 contacting the doped liner 312. The WL structure can correspond to the gate terminal located between the doped liner 312 and the other of the source or drain portion located on the opposite end of the semiconductor path 314. The WL structure can control activation of the access device 204 (e.g., the corresponding transistor) to form/activate a current channel between the source and the drain terminals, thereby allowing access to the data or the charge level stored on the corresponding double-sided capacitor 302.

The doped liner 312 can provide dopants that diffuse into the semiconductor path 314, thus providing a mechanism for doping the cell-contact junction for the 3D device that is different from conventional doping mechanisms used for 2D device manufacturing. Moreover, the doped liner 312 can effectively increase the contact between the semiconductor path 314 and the coupled capacitor structure.

Each double-sided capacitor 302 can include a bottom electrode structure 322 that surrounds a top electrode structure 324. The top and bottom electrodes 322 and 324 can include electrically conductive structures, such as titanium nitride (TiN). The top and bottom electrodes 322 and 324 can be separated, with a layer of a high-dielectric (high-K) layer 326 disposed between the electrodes 322 and 324. In some embodiments, the top and bottom electrodes 322 and 324 can have box-like shapes with rectangular cross sections. The top and bottom electrodes 322 and 324 and the high-K layer 326 can be concentrically arranged.

As described above, instances of the double-sided capacitor 302 can be arranged along a column that extends across the stacked layers 212. Each column of the double-sided capacitors 302 can be surrounded by deep trench isolations (DTIs) 330 as shown in FIG. 3B. A separate high-K layer, a separate electrode-like structure (e.g., common material), or a combination thereof can be disposed between vertically adjacent instances of the double-sided capacitor 302. For example, an interrupting structure having a high-K layer and an electrode-like layer can be disposed between a top portion 332 and a bottom portion 334 (e.g., opposing portions of the bottom electrode 322) of a pair of vertically stacked capacitors. Moreover, the separate high-K layer can extend inward and contact peripheral portions of the access device 204. In doing so, the separate high-K layer can effectively define an upper edge and a lower edge for the doped liner 312. Side portions 336 of each double-sided capacitor 302 can contact anchoring liner structures 338 that provide stability and structural integrity for the double-sided capacitor 302 relative to the DTIs 330. The anchoring liner structures 338 can effectively function as containers for the double-sided capacitors 302. The anchoring liner structures 338 can function as extended Si material that couples to and effectively increases the contact area between the semiconductor path 314 and the coupled capacitor structure. Since the contact resistance is inversely proportional to the contact area, the doped liners 312 each integral with the anchoring liner structures 338 can decrease the contact resistance between the double-sided capacitors 302 and the coupled access devices 204.

In some embodiments, the bottom electrode 322 and/or the top electrode 324 can have hollow cylindrical or prism shapes with respective circular or polygonal cross sections (e.g., rectangular cross section as shown in FIG. 3B). For example, the top portion 332, the bottom portion 334, and the side portions 336 can be laterally extending sections of the bottom electrode 322. The top portion 332, the bottom portion 334, and the side portions 336 can be integral with and extend laterally away from an inner portion 331. The bottom electrode 322 can at least partially surround the top electrode 324, such as for concentric arrangements.

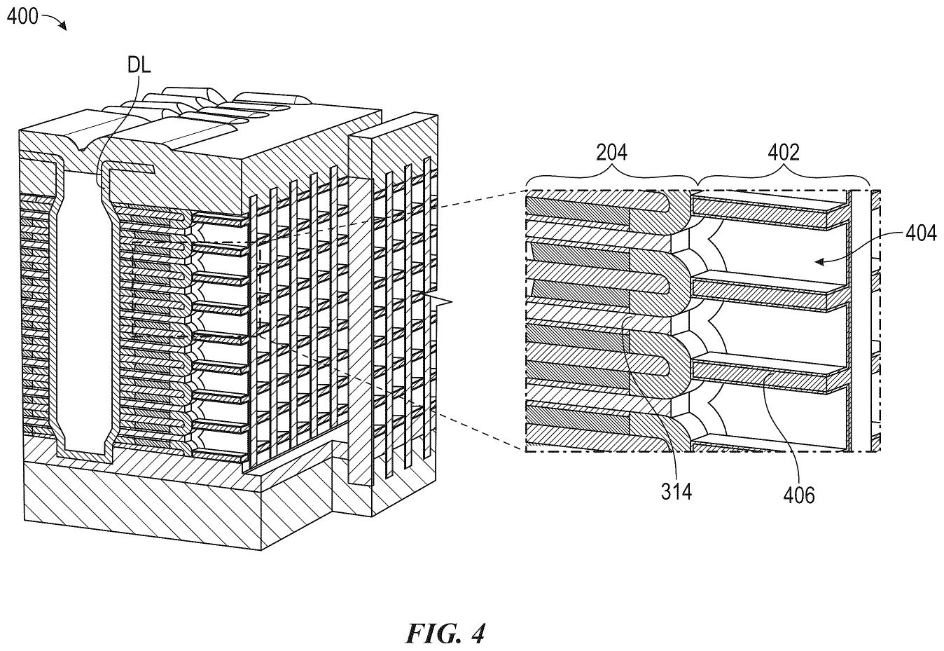

One or more characteristics of the double-sided capacitor 302, the doped liner 312, etc. described above can result from related manufacturing steps. FIG. 4-FIG. 13 and FIG. 15 illustrate example stages in manufacturing the example 3D semiconductor device in accordance with an embodiment of the present technology. FIG. 4 is a perspective cut away view of a structure 400, along with a detailed view of a portion therein. The structure 400 can represent to a state following formation of the access devices 204 by depositing, shaping, and removing various materials relative to a semiconductor (Si) frame structure. For example, the structure 400 can include a digit line (DL) structure extending vertically across the stacked layers 212. The access devices 204 can contact the DL at one end (e.g., one terminal portion, such as a source or a drain) and extend away or toward peripheral portion. Each of the access devices 204 can include a word line (WL) disposed between protective or insulative structures (e.g., Si₃N₄ structures) along a lateral direction. The WL can surround the semiconductor path 314, which may include SiGe. Vertically stacked instances of the access devices 204 can be separated by a protective layer, such as a SiO₂ structure.

The access devices 204 can extend toward a capacitor designated region 402 located opposite the DL. The capacitor designated region 402 can have dividers that define slots or depressions for housing the capacitors 202 of FIG. 2 (e.g., the double-sided capacitors 302 of FIG. 3). The capacitor designated region 402 and the dividers can be formed based on etching away divisions from Si block, depositing a protective coating (e.g., SiO₂) on the walls of the divisions, and filling the remaining divisions in the Si block with non-conductive material (e.g., Si₃N₄). The coated and deposited material can be removed from peripheral surfaces to re-expose the Si block for subsequent recessing/removal process. Thus, the Si material between the divisions can be removed to form the capacitor housing slots 404, and the remaining portions of the protective coating and the non-conductive material can become slot dividers 406.

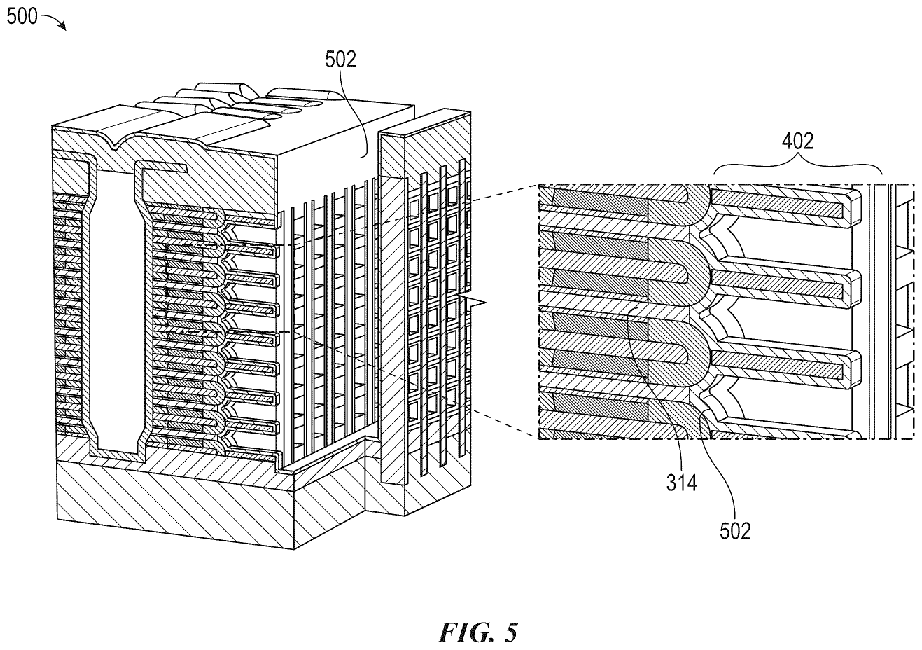

FIG. 5 is a perspective cut away view of a structure 500, along with a detailed view of a portion therein. The structure 500 can represent a result of depositing a doped Si layer 502 on the structure 400 of FIG. 4. In some embodiments, the doped Si layer 502 can include phosphine-doped Si that is deposited via chemical vapor deposition (CVD).

Accordingly, the doped Si layer 502 can cover the capacitor designated region 402 and coat/occupy the capacitor housing slots. Further the doped Si layer 502 can directly contact the peripheral portions or surfaces of the semiconductor paths 314. The doped Si layer 502 can be shaped as described below to form the doped liner 312 of FIG. 3A and the anchoring liner structures 338 of FIG. 3B. The direct contact between the semiconductor paths 314 and the doped Si layer 502 can provide the diffused doping for the 3D device as described above.

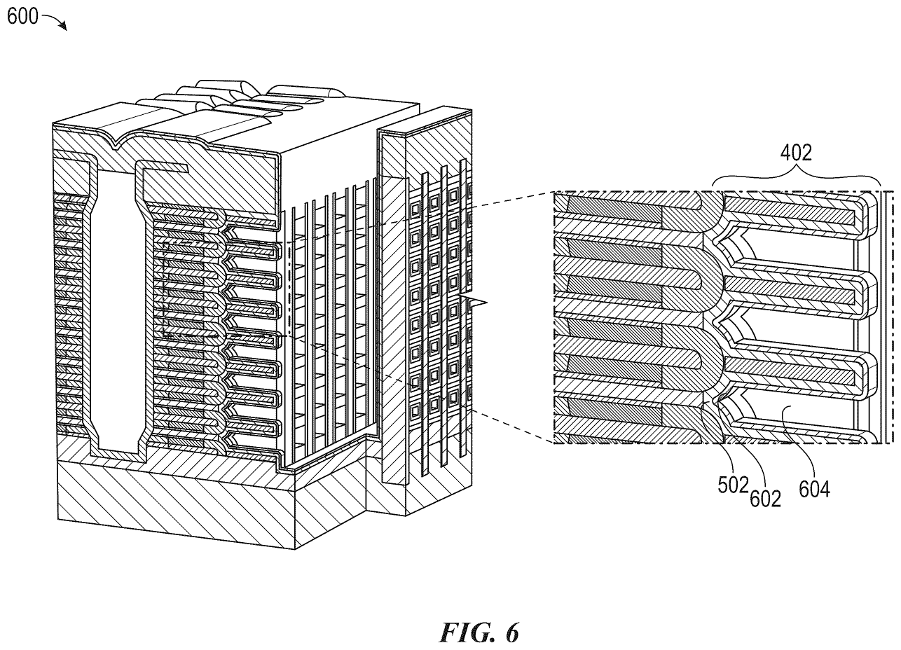

FIG. 6 is a perspective cut away view of a structure 600, along with a detailed view of a portion therein. The structure 600 can represent a result of depositing an electrode forming layer 602 and then an inner protective layer 604 onto the structure 500 of FIG. 5. The electrode forming layer 602 and the inner protective layer 604 can coat the walls (e.g., over the doped Si layer 502) in the capacitor designated region 402. The electrode forming layer 602 can include conductive material (e.g., TiN) that can be shaped as described below to form the bottom electrode 322 of FIG. 3A. The electrode forming layer 602 can be disposed between the doped Si layer 502 and the inner protective layer 604. The inner protective layer 604 can include non-conductive or oxide material (e.g., SiO₂) configured to protect the inside portions of the electrode forming layer 602 from subsequent recess or etch process.

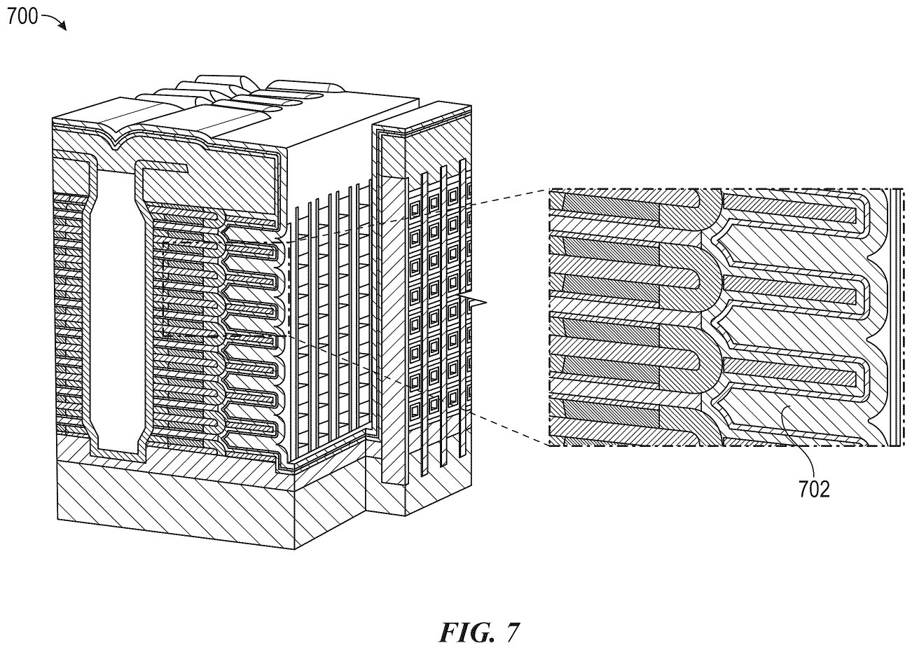

FIG. 7 is a perspective cut away view of a structure 700, along with a detailed view of a portion therein. The structure 600 can represent a result of depositing sidewall protection layer 702 onto the structure 600 of FIG. 6. The sidewall protection layer 702 can directly contact the inner protective layer 604 and fill the space remaining in the capacitor housing slots. The sidewall protection layer 702 can include non-conductive material (e.g., Si₃N₄) configured to protect sidewalls and bottom portions of the electrode forming layer 602 that are shaped as described below to form the bottom portion 334 of FIG. 3B and the side portions 336 of FIG. 3B.

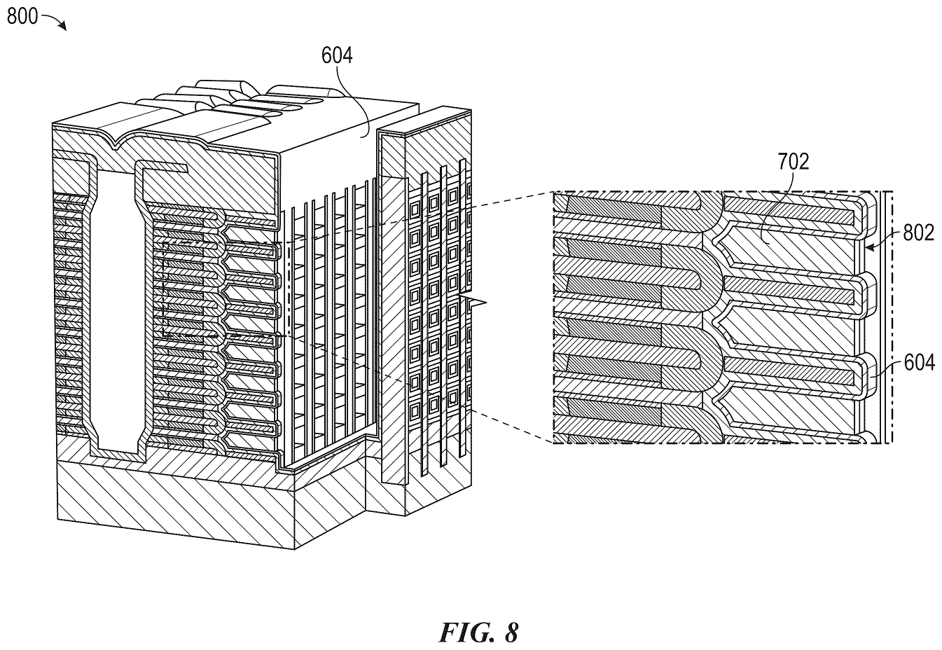

FIG. 8 is a perspective cut away view of a structure 800, along with a detailed view of a portion therein. The structure 800 can represent a result of recessing a portion of the sidewall protection layer 702 from the structure 700 of FIG. 7. The recessing process can utilize a mechanism, such as an etching agent or a controlled removal depth, that exposes peripheral portions of the inner protective layer 604. For example, the recessing process can be performed selectively to the SiO₂ layer. As a result, isolated portions of the sidewall protection layer 702 can occupy the capacitor housing slot, and the remaining side wall protection layer 702 can have a capacitor-inner recess 802 characteristic of the recessing process.

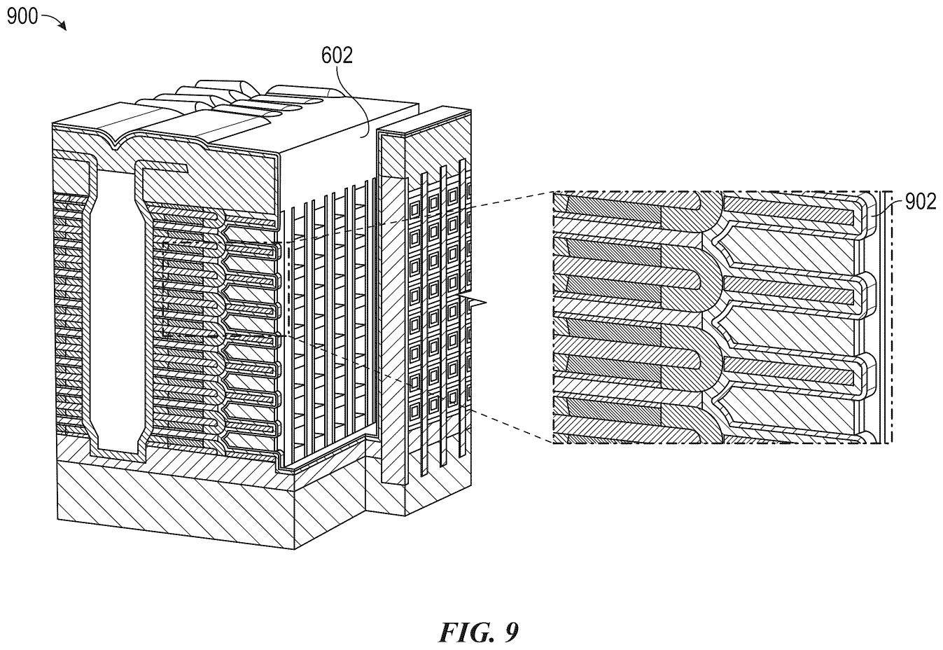

FIG. 9 is a perspective cut away view of a structure 900, along with a detailed view of a portion therein. The structure 900 can represent a result of recessing a portion of the inner protective layer 604 of FIG. 8 from the structure 800 of FIG. 8. The recessing process can utilize a mechanism, such as an etching agent or a controlled removal depth, that exposes electrode connecting portions 902 (e.g., peripheral portions of the electrode forming layer 602). For example, the recessing process can be performed selectively to the TiN layer and the Si₃N₄ layer.

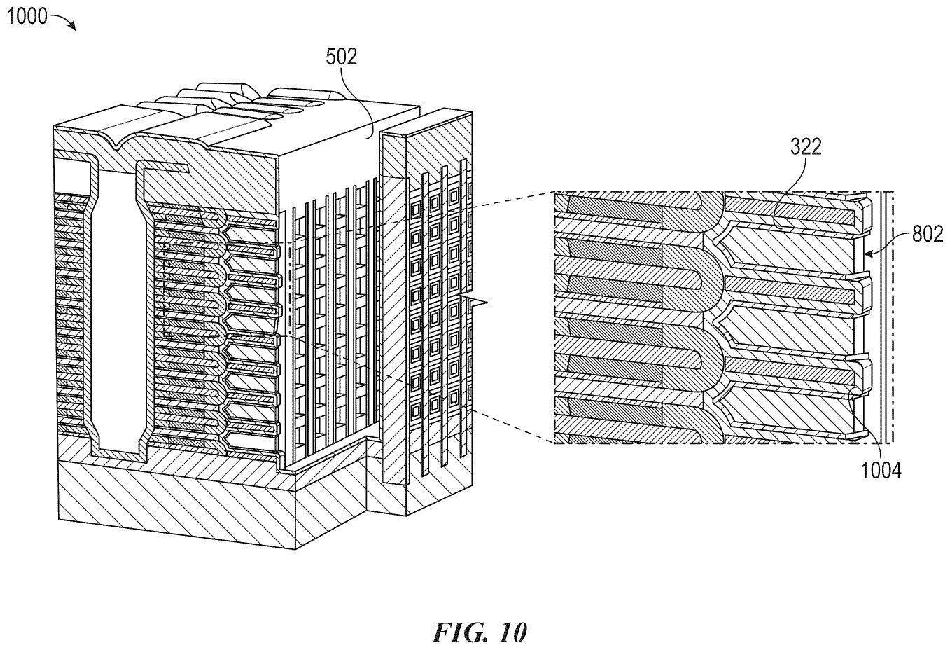

FIG. 10 is a perspective cut away view of a structure 1000, along with a detailed view of a portion therein. The structure 1000 can represent a result of recessing exposed portions of the electrode forming layer 602 of FIG. 9 from the structure 900 of FIG. 9. The recessing process can utilize a mechanism, such as an etching agent or a controlled removal depth, that removes the exposed electrode connecting portions 902 of FIG. 9. For example, the recessing process can be performed selectively to the Si layer, the SiO₂ layer, the Si₃N₄ layer, or a combination thereof.

The remaining portions of the electrode forming layer 602 can be effectively shaped or separated into individual structures within the capacitor housing slots. The remaining portions of the electrode forming layer 602 can extend laterally out to the capacitor-inner recess 802. Thus, the remaining portions of the electrode forming layer 602 can include the bottom electrodes 322. Further, removing the electrode connecting portions 902 can expose liner connection portions 1004 (e.g., peripheral portions of the doped Si layer 502 of FIG. 5).

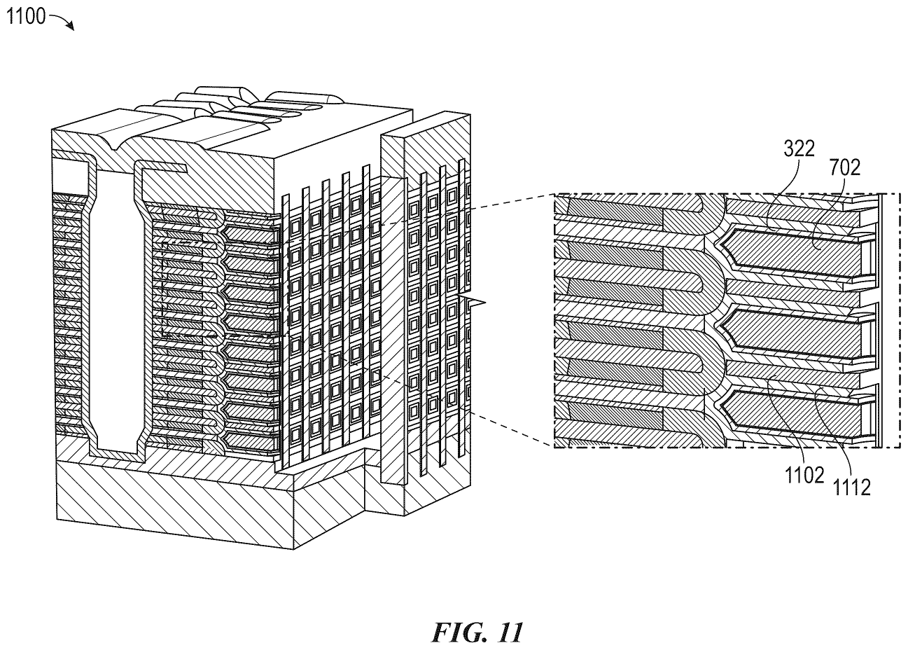

FIG. 11 is a perspective cut away view of a structure 1100, along with a detailed view of a portion therein. The structure 1100 can represent a result of recessing or removing the liner connection portions 1004 of FIG. 10 from the structure 1000 of FIG. 10. The recessing process can utilize a mechanism, such as an etching agent or a controlled removal depth, that removes the liner connection portions 1004 (e.g., the exposed portions of the poly-Si). For example, the recessing process can be performed selectively to the TiN layer, the SiO₂ layer, the Si₃N₄ layer, or a combination thereof.

The recessing process can expose a peripheral portion of dividers 1102 (e.g., the non-conductive material therein as described above with respect to FIG. 4). Further, the recessing process can form adjacent liner portions 1112 (e.g., remaining portions of the doped Si layer 502 of FIG. 5) that each occupy one capacitor housing slot. Each of the adjacent liner portions 112 can surround the sidewall protection layer 702 remaining in the capacitor housing slot and contact or abut the dividers 1102 that are above and below the capacitor housing slot.

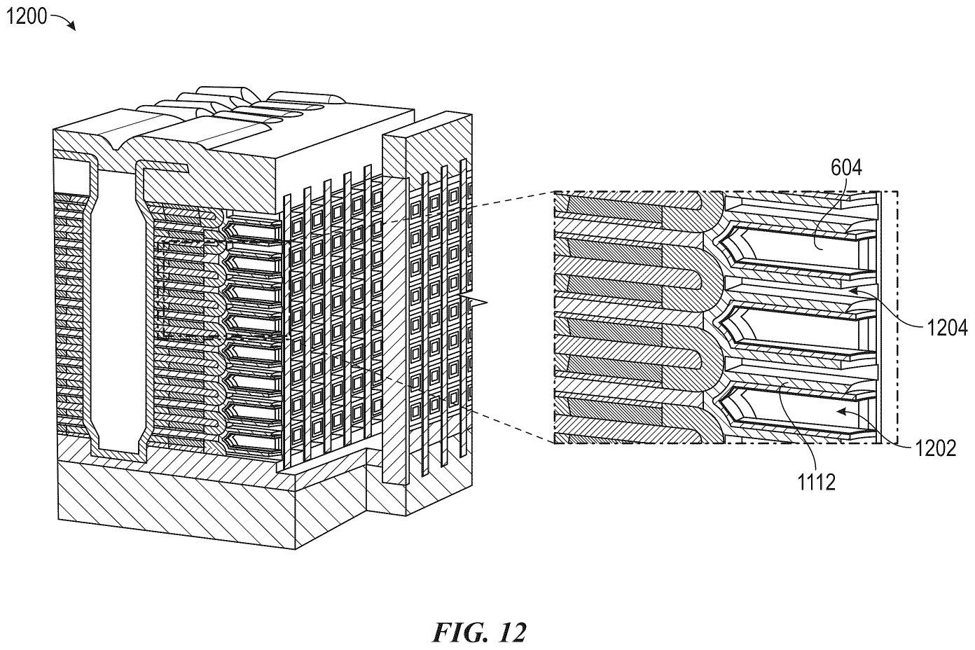

FIG. 12 is a perspective cut away view of a structure 1200, along with a detailed view of a portion therein. The structure 1200 can represent a result of recessing or removing the sidewall protection layer 702 of FIG. 11 and the dividers 1102 of FIG. 11 from the structure 1100 of FIG. 11. The recessing process can utilize a mechanism, such as an etching agent or a controlled removal depth, that removes exposed portions of the protective material (e.g., Si₃N₄). For example, the recessing process can be performed selectively to the TiN layer, the SiO₂ layer, the Si layer, or a combination thereof. Also, the recessing process can occur along lateral directions, such as from a peripheral end of the capacitor designated region 402 of FIG. 4 and proceed inward toward the access devices 204 of FIG. 4.

The recessing process can form slot-inner cavities 1202 that expose the inner protective layer 604 within each of the capacitor housing slots. Further, the recessing process can form slot-adjacent cavities 1204 that expose the adjacent liner portions 1112 (e.g., top and bottom surfaces thereof) on the boundaries of the capacitor housing slots.

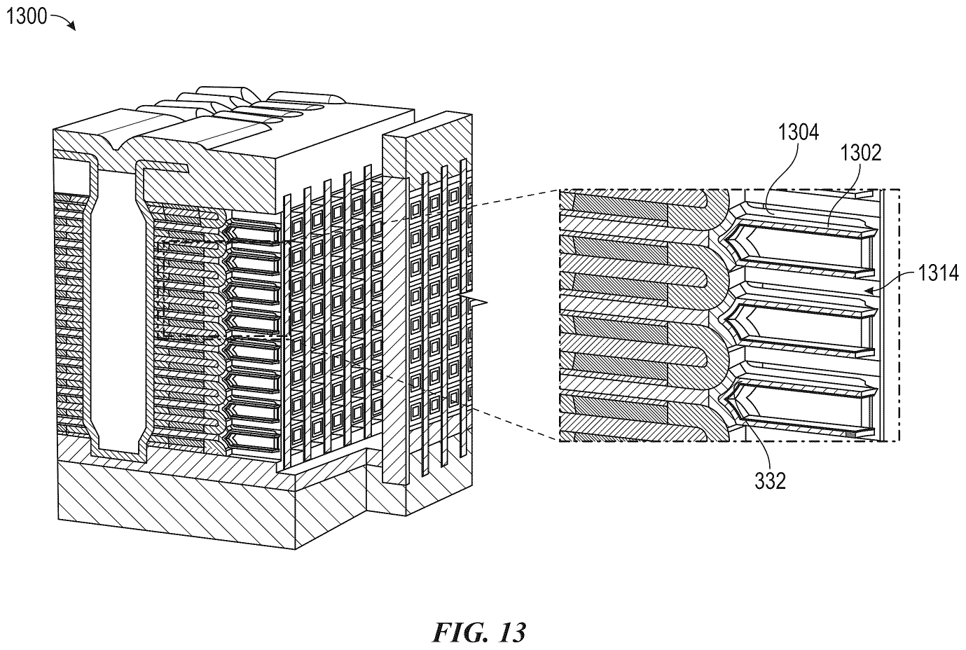

FIG. 13 is a perspective cut away view of a structure 1300, along with a detailed view of a portion therein. The structure 1300 can represent a result of recessing or removing portions of the adjacent liner portions 1112 of FIG. 12 from the structure 1200 of FIG. 12. The recessing process can utilize a mechanism, such as an etching agent or a controlled removal depth, that removes portions of the doped Si layer 502 of FIG. 5 (e.g., the poly-Si). For example, the recessing process can be performed selectively to the TiN layer, the SiO₂ layer, the Si₃N₄ layer, or a combination thereof. The recessing mechanism can be applied to the adjacent liner portions 1112 through the slot-adjacent cavities 1204 of FIG. 12. The recessing process can reveal exposed electrode surfaces 1302 for the bottom electrode 322. Further, the recessing process can form a widened adjacent cavity 1314 as a result of removing the poly-Si to widen the slot-adjacent cavity 1204 of FIG. 12.

In some embodiments, the recessing process can utilize multiple steps or related mechanisms. For example, the recessing process can utilize a first etching mechanism (e.g., hydrofluoric acid (HF) decap agent, ammonia (NH₄OH), other similar agents, or a combination thereof) with broad or indiscriminate removal capabilities and then a second etching mechanism (e.g., HF decap, tetramethylammonium hydroxide (TMAH), other similar agents, or a combination thereof) with a self-limiting characteristic. The first etching mechanism can be used to remove a majority of the adjacent liner portions 1112. FIG. 13 can represent the state following application of the first etching mechanism. Accordingly, the structure 1300 can include remaining filler portions 1304 over a space between the bottom electrode 322 and the DTI 330 of FIG. 3B. The portion of the remaining filler portions 1304 extending beyond the exposed electrode surface 1302 (e.g., above the top portion 332 of FIG. 3B and below the bottom portion of 334 of FIG. 3B) can be removed using the second etching mechanism. The recessing process can leverage the self-limiting characteristic, such as for removing the targeted material (e.g., the poli-Si) in proportion to the exposed surface area, to selectively etch a portion of the remaining filler portions 1304 and leave a portion thereof. The resulting remaining filler portions 1304 can be the anchoring liner structures 338 of FIG. 3B.

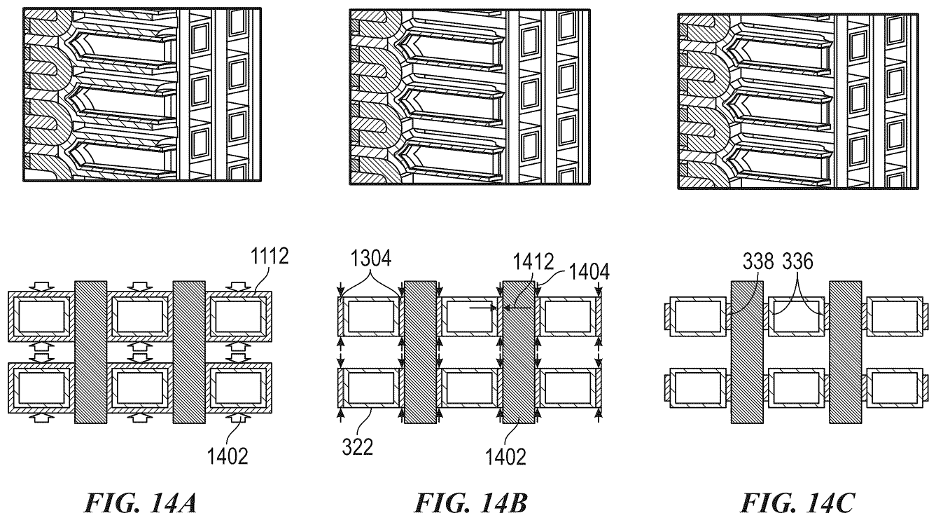

To further illustrate the multi-step etching process, FIG. 14A-FIG. 14C are detailed views of structures shown in FIGS. 11, 12, and 13 in accordance with an embodiment of the present technology. FIG. 14A can illustrate the application of a first etching mechanism 1402 (e.g., etchant including ammonia) to the structure 1100 of FIG. 11 or the structure 1200 of FIG. 12. The first etching mechanism 1402 can be applied to the liner connection portions 1004 of FIG. 10, the adjacent liner portions 1112 (e.g., through the slot-adjacent cavities 1204 of FIG. 12), or both. The amount of the first etching mechanism 1402 and/or an application duration can be monitored and controlled to limit the amount of removal.

FIG. 14B can illustrate the application of a second etching mechanism 1404 to the structure 1300 of FIG. 13. The second etching mechanism 1404 (e.g., etchant including TMAH) can have the self-limiting characteristics, such as for removing or reacting to a limited depth. As a result, the second etching mechanism 1404 can remove a limited volume under the exposed surface without continuing to remove or react with the material below.

The second etching mechanism 1404 can be applied to remove the top and bottom portions of the remaining filler portion 1304 without removing the portions occupying separation spaces 1412 between the bottom electrodes 322 and stabilizing structures 1414 that will be subsequently manipulated or removed to form the DTI 330 of FIG. 3. The recessing process can leverage the shape and size (e.g., relatively narrow/short width of the space in comparison to the depth/height) of the separation spaces 1412 and the related self-limiting characteristic of the second etching mechanism 1404 (e.g., the TMAH) to retain the remaining filler portions 1304 in the separation spaces 1412. The geometry of the separation spaces 1412 can limit the entering amount of the second etching mechanism 1404, thereby providing the self-limiting feature. In some embodiments, the recessing process can leverage the second or self-limiting etching mechanism 1404 directly to the structure 1200 of FIG. 12 without first applying the first etching mechanism 1402. The amount of the second etching mechanism 1404 and/or an application duration can be monitored and controlled to limit the amount of removal.

FIG. 14C can illustrate the result of the controlled recessing step(s). The remaining filler portions 1304 of FIG. 14B in the separation spaces 1412 of FIG. 14B can become the anchoring liner structures 338. The anchoring liner structures 338 can be rigid and directly contact and adhere to the side portions 336 of the bottom electrodes 322, thereby providing additional structural support for the resulting capacitors 202 of FIG. 2. In some embodiments, the side portions 336 can be shorter than the height of the bottom electrode 322 and positioned between the top and bottom portions 332 and 334 as a characteristic of using the self-limiting second etching mechanism 1404. For example, the top and bottom portions of the side portions 336 can form an indent or a depression relative to the top and bottom portions 332 as a result of the second etching mechanism 1404 partially etching away the poly-Si material before being affected by the self-limiting characteristic.

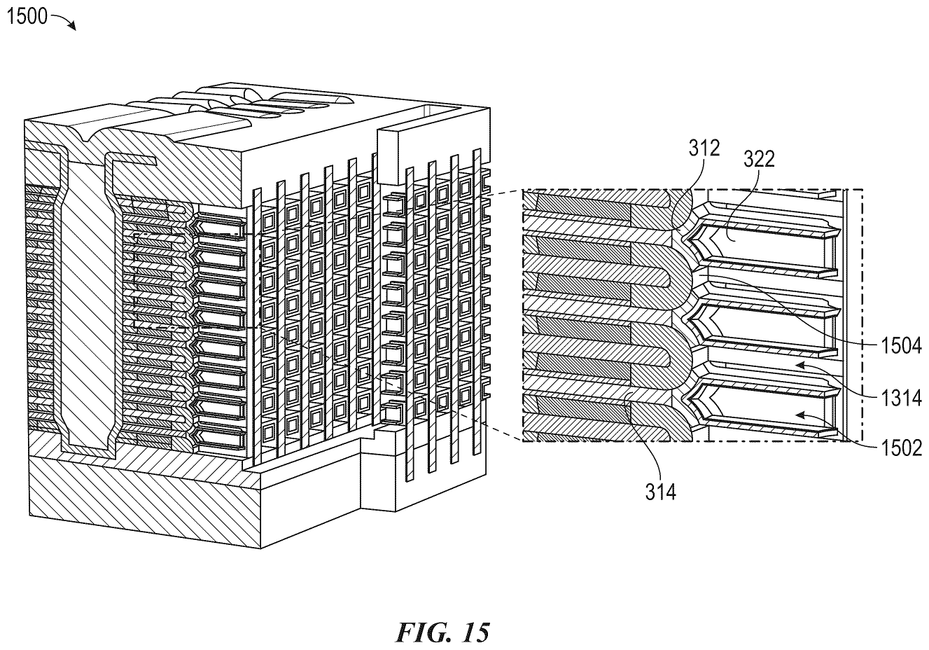

FIG. 15 is a perspective cut away view of a structure 1500, along with a detailed view of a portion therein. The structure 1500 can represent a result of recessing or removing exposed portions of protective material (e.g., oxides, such as SiO₂) from the structure 1300 of FIG. 13 or the structure represented in FIG. 14C. The recessing process can utilize a mechanism, such as an etching agent or a controlled removal depth, that removes portions of the protective material. For example, the recessing process can be performed selectively to the TiN layer, the Si layer, the Si₃N₄ layer, or a combination thereof.

The recessing can correspond to shaping the doped liners 312 and the bottom electrode 322 along with the widened adjacent cavities 1314 or similar surrounding portions in the structure 1500. Moreover, the recessing can expose capacitor inner cavities 1502 within the bottom electrodes 322. The portions surrounding the doped liners 312 and the bottom electrode 322, such as the widened adjacent cavities 1314 and the capacitor inner cavities 1502 can be filled with additional layers or components during subsequent manufacturing steps to form the double-sided capacitors 302 of FIG. 3A and FIG. 3B and the overall 3D device 200 of FIG. 2. For example, materials for the high-K layer 326 of FIG. 3A and the top electrode 324 can be deposited and shaped/etch to form the double-sided capacitors 302 and the separating structures shown in FIG. 3A and FIG. 3B. The depositing and recessing processes for such materials can be similar to one or more of the manufacturing processes described above.

Further, the recessing can expose access device boundaries 1504 at or about the peripheral edges of the doped liners 312. The subsequently deposited material (e.g., the high-K material) can directly contact the access device boundaries 1504 to electrically isolate each of the double-sided capacitors 302 from circuits/capacitors above and below.

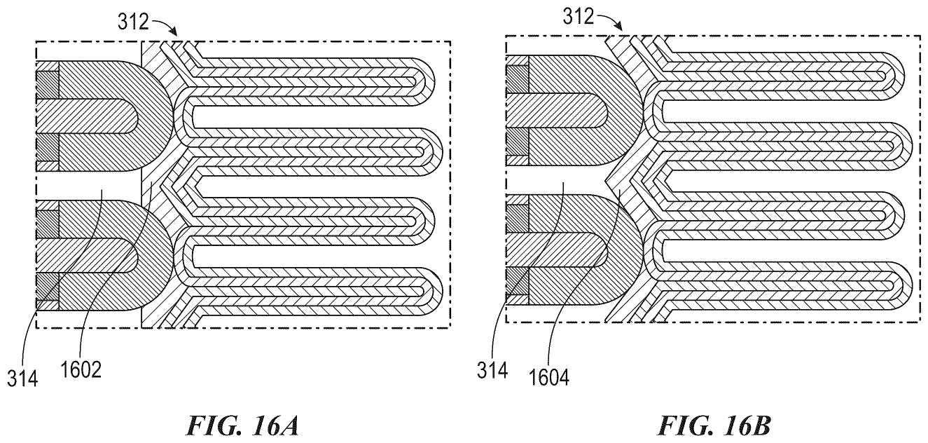

FIG. 16A is a detailed view of a first example capacitor configuration 1602 (e.g., a flattened shape configuration) in accordance with an embodiment of the present technology. The doped liner 312 can have the first configuration 1602 having a generally planar surface contacting the semiconductor path 314. The first capacitor configuration 1602 can result from using a first etching process (e.g., Selis vapor etch), such as in forming the structure 400 of FIG. 4. The first capacitor configuration 1602 can provide robust tier-to-tier Si path length variations (e.g., consistent path lengths across the stacked layers 212).

FIG. 16B is a detailed view of a second example capacitor configuration 1604 (e.g., a protruding shape configuration) in accordance with an embodiment of the present technology. The doped liner 312 can have the second configuration 1604 having a portion (e.g., a pointed tip) protruding into the semiconductor path 314. In other words, the doped liner 312 can have a generally triangular or a peak shape as shown in FIG. 16B for the second capacitor configuration 1604. The second capacitor configuration 1604 can result from using a second etching process (e.g., etchant including TMAH or ammonia), such as in forming the structure 400 of FIG. 4. The second capacitor configuration 1604 can provide increased contact area at the junction between the doped liner 312 and the semiconductor path 314.

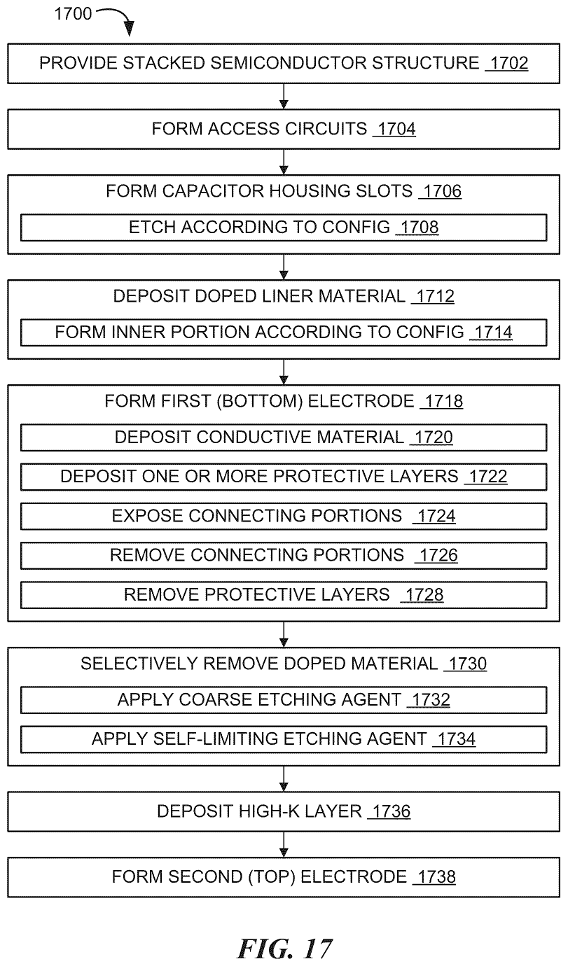

FIG. 17 is a flow diagram illustrating an example method 1700 of manufacturing a semiconductor device (e.g., the apparatus 100 of FIG. 1, the 3D semiconductor device 200, the structures described above with respect to FIGS. 4-15, or a combination thereof) having a capacitor with a doped liner in accordance with an embodiment of the present technology. For example, the method 1700 can be for manufacturing the double-sided capacitor 302 of FIG. 3A with the doped liner 312 of FIG. 3A (e.g., including the integral anchoring liner structures 338 of FIG. 3B). The method 1700 can be related to (e.g., representing one or more portions or combinations of) the stages and features illustrated in FIG. 4-FIG. 15.

The method 1700 can include providing a stacked semiconductor structure as shown at block 1702. The provided structure can include layers of semiconductor material (e.g., Si/SiGe) disposed between oxide layers. Each layer of semiconductor material and surrounding portions of the oxide layers can represent a circuit layer.

At block 1704, the access devices 204 of FIG. 2 (e.g., transistors) can be formed on the stacked semiconductor structure. For example, forming the access devices can include shaping the layers of the semiconductor material, the oxide layers, or a combination thereof and doping one or more targeted regions to form DTIs, dielectric fills, terminal regions and connectors (e.g., DL structure), gate connections (e.g., WL structures), or the like. The formed access devices can each include the semiconductor path 314 of FIG. 3 that is configured to selectively (e.g., according to the activation state of the related transistor) provide or break an electrical path.

At block 1706, the capacitor housing slots 404 of FIG. 4 can be formed on the stacked semiconductor structure. Forming the capacitor housing slots 404 can include removing portions of the stacked semiconductor structure or any protective material on the structure from portions adjacent to peripheral ends of the access devices 204. The formed capacitor housing slots 404 can expose a peripheral portion of the semiconductor path 314.

In some embodiments, the formation of the capacitor housing slots 404 can include an etching process that targets a specific configuration as shown in block 1708. For example, the capacitor housing slots 404 can be formed by implementing a vapor based etch (e.g., Selis vapor etch) that forms a planar surface on the peripheral end portion of the semiconductor path 314. The planar surface can be representative of the flattened configuration 1602 of FIG. 16A. Also, the capacitor housing slots 404 can be formed by implementing a liquid based etch (e.g., TMAH, ammonia, or the like) that forms a depression on the peripheral end portion of the semiconductor path 314. The depression can be representative of the protruding configuration 1604 of FIG. 16B. Blocks 1702-1708 can correspond to the manufacturing steps that produce the structure 400 of FIG. 4.

At block 1712, the doped liner material (e.g., the phosphine-doped Si) can be deposited onto the structure. Accordingly, the doped Si layer 502 of FIG. 5 can be formed as described above for the structure 500 of FIG. 5. The doped liner material can contact and at least partially cover the capacitor housing slots 404 of FIG. 4, including the exposed peripheral portion of the semiconductor path 314, as described above for the structure 500 of FIG. 5. Accordingly, the doped liner material can conform to the shape of the semiconductor path 314. As illustrated in block 1714, the deposition of the liner material can include forming the inner or interfacing portion of the doped liner 312 of FIG. 3A. For example, the resulting interfacing portion can have a planar end surface according to the flattened configuration 1602 of FIG. 16A or a protrusion that extends into the semiconductor path 314 according to the protruding configuration 1604 of FIG. 16B.

Depositing the doped liner material directly on the semiconductor path 314 can effectively include doping the semiconductor path 314. Dopants can move from the doped liner material to the semiconductor path 314 through diffusion.

At block 1718, the first electrodes (e.g., the bottom electrodes 322 of FIG. 3A) in forming the capacitors in the capacitor housing slots 404 of FIG. 4 as described above with respect to FIGS. 6-10. For example, as illustrated in block 1720, forming the bottom electrodes 322 can include depositing conductive material (e.g., TiN). The deposited conductive material can form the electrode forming layer 602 described above with respect to FIG. 6. The electrode forming layer 602 can directly contact and coat the doped Si layer 502 in the capacitor housing slots 404. Further, the electrode forming layer 602 can include the electrode connecting portions 902 that extend between adjacent capacitor housing slots 404.

At block 1722, one or more protective layers can be applied or deposited over the electrode forming layer 602 (e.g., to the structure 600 of FIG. 6). For example, the inner protective layer 604 of FIG. 6, the sidewall protection layer 702 of FIG. 7, or a combination thereof can be applied over the electrode forming layer 602 as described above with respect to FIG. 6 and FIG. 7.

At block 1724, the electrode connecting portions 902 of FIG. 9 can be exposed, such as by removing and shaping portions of the protective layers. For example, portions of the inner protective layer 604 of FIG. 6, the sidewall protection layer 702 of FIG. 7, or a combination thereof can be recessed or etched away, such as from peripheral ends of the manipulated structure, as described above with respect to FIG. 8 and FIG. 9.

At block 1726, the electrode connecting portions 902 of FIG. 9 can be removed to form each of the bottom electrodes 322 from the electrode forming layer 602. For example, the electrode connecting portion 902 can be recessed or etched away as described above with respect to FIG. 10. Removing the electrode connecting portions 902 can include shaping the electrode forming layer 602 to effectively singulate or isolate each of the bottom electrodes 322. As a result, the remaining portions of the electrode forming layer 602 can form the inner portion 331 of FIG. 3A closest to the semiconductor path 314 of FIG. 3A and integral with the top portion 332 of FIG. 3B, the bottom portion 334 of FIG. 3B, and the side portions 336 of FIG. 3B that extend laterally away from the semiconductor path 314.

At block 1728, the protective layers surrounding the bottom electrodes 322 can be removed. For example, the protective material corresponding to the dividers 1102 of FIG. 2, the sidewall protection layer 702, and/or the like can be removed as described above with respect to FIG. 12. Accordingly, portions of the bottom electrodes 322, such as the top portion 332, the bottom portion 334, and its inner surfaces can be exposed.

At block 1730, portion of the doped poly-Si material (e.g., the adjacent liner portion 1112 of FIG. 12) can be selectively removed. For example, the adjacent liner portion 1112 initially covering the top and bottom outer surfaces of the bottom electrode 322 can be etched away as described above with respect to FIGS. 11-14C. Accordingly, portions of the bottom electrodes 322, such as the top portion 332 and the bottom portion 334 can be exposed.

The removal process can be selective in that the doped poly-Si material remains between the inner portion of the bottom electrodes 322 and the semiconductor paths 314. Additionally, the anchoring liner structures 338 of FIG. 3B can remain as a result of the selective removal step. For example, at block 1732, the method 1700 can include application of coarse etching agent (e.g., the first etching mechanism 1402 of FIG. 14A) as described above with respect to FIG. 14A. The coarse etching agent can least partially remove portions of the adjacent liner portion 1112 initially contacting the top and bottom portions 332 and 334 of the bottom electrode 322. At block 1734, the self-limiting etching agent (e.g., the second etching mechanism 1404 of FIG. 14B, such as TMAH) can be applied. The removal caused by the applied agent can be limited to portions of the adjacent liner portion 1112 initially contacting the top and bottom portions of the bottom electrode, thereby retaining portions of the doped Si layer 502 contacting the side portions 336. The removal of portions of the doped Si layer 502 adjacent to the side portions 336 (e.g., in and/or above the separation spaces 1412) can be limited according to a geometry or one or more dimensions associated with separation spaces 1412. The remaining portions of the doped Si layer 502 in the separation spaces 1412 can correspond to the anchoring liner structures 338 of FIG. 3B.

At block 1736, the high-K layer 326 of FIG. 3A can be deposited over the shaped bottom electrodes 322 for forming the capacitors (e.g., the double-sided capacitors 302 of FIG. 3A). Further, at block 1738, an additional layer of conductive material can be deposited over the high-K layer to form the capacitors. The additional layer of conductive material can be used as or further manipulated to form the top electrode 324 of FIG. 3A.

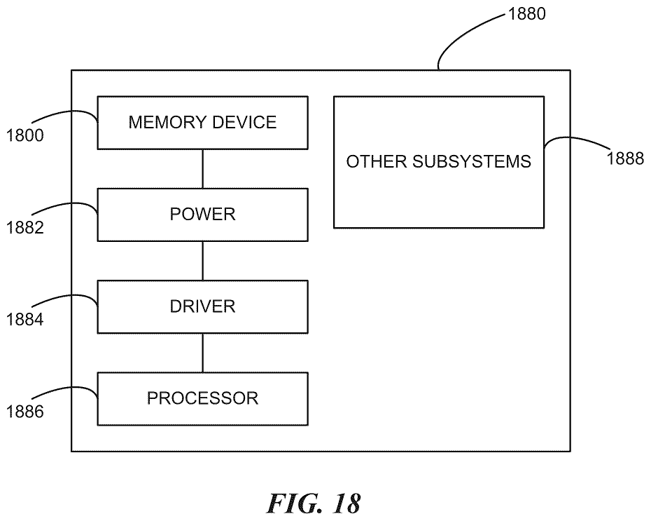

FIG. 18 is a schematic view of a system that includes an apparatus in accordance with embodiments of the present technology. Any one of the foregoing apparatuses (e.g., memory devices) described above with reference to FIGS. 1-17 can be incorporated into any of a myriad of larger and/or more complex systems, a representative example of which is system 1880 shown schematically in FIG. 18. The system 1880 can include a memory device 1800, a power source 1882, a driver 1884, a processor 1886, and/or other subsystems or components 1888. The memory device 1800 can include features generally similar to those of the apparatus described above with reference to FIGS. 1-17, and can therefore include various features for performing a direct read request from a host device. The resulting system 1880 can perform any of a wide variety of functions, such as memory storage, data processing, and/or other suitable functions. Accordingly, representative systems 1880 can include, without limitation, hand-held devices (e.g., mobile phones, tablets, digital readers, and digital audio players), computers, vehicles, appliances and other products. Components of the system 1880 may be housed in a single unit or distributed over multiple, interconnected units (e.g., through a communications network). The components of the system 1880 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-18.

I/We claim:

1. A memory device, comprising:
a double-sided, lateral capacitor having a first electrode and a second electrode with a high-dielectric (high-K) layer disposed there between, wherein the first electrode at least partially surrounds the second electrode;
an access device including a lateral semiconductor path coupled to the capacitor; and
an N+ poly-silicon (Si) liner disposed between the capacitor and the access device, wherein the doped liner electrically connects the lateral semiconductor path to the first electrode.

2. The memory device of claim 1, wherein the N+ poly-Si liner provides dopants for the lateral semiconductor path through diffusion.

3. The memory device of claim 1, wherein the N+ poly-Si liner has a planar surface that contacts the lateral semiconductor path.

4. The memory device of claim 1, wherein the N+ poly-Si liner has an inner portion that that protrudes into the lateral semiconductor path.

5. The memory device of claim 1, wherein:
the first electrode has a hollow prism shape with a top portion, a bottom portion, and side portions extending laterally away from the access device; and
the poly-Si liner includes anchoring liner structures that extend laterally covering and directly contacting the side portions of the first electrode.

6. A method of manufacturing a memory device, the method comprising:
forming a semiconductor path of an access device in a layer of semiconductor material, wherein the layer of semiconductor material is disposed between dielectric layers;
forming a capacitor housing slot at a peripheral end of the access device, wherein the capacitor housing slot is defined by laterally extending slot dividers and an exposed peripheral end portion of the semiconductor path;
depositing a doped poly-Si material in the capacitor housing slot, wherein the deposited doped poly-Si material directly contacts and at least partially covers the peripheral end portion of the semiconductor path;
forming a first electrode of a capacitor in the capacitor housing slot,
wherein the first electrode directly contacts the doped poly-Si material in the capacitor housing slot, and
wherein the first electrode includes an inner portion closest to the semiconductor path and integral with top, bottom, and side portions that extend laterally away from the inner portion;
selectively removing portions of the doped poly-Si material to expose the top and bottom portions of the first electrode, wherein the doped poly-Si material remains between the inner portion of the first electrode and the semiconductor path; and
depositing a high-K layer on at least inner surfaces of the first electrode and a second electrode on the high-K layer.

7. The method of claim 6, wherein:
forming the capacitor housing slot includes implementing a vapor based etch that forms a planar surface on the peripheral end portion of the semiconductor path; and
depositing the doped poly-Si material includes depositing the doped liner contacting the planar surface for providing a planar end surface for a resulting doped liner.

8. The method of claim 6, wherein:
forming the capacitor housing slot includes implementing a liquid based etch that forms a depression on the peripheral end portion of the semiconductor path; and
depositing the doped poly-Si material includes depositing the doped liner contacting and filling the depression for providing a protrusion for a resulting doped liner that extends into the semiconductor path.

9. The method of claim 6, wherein selectively removing the portions of the doped poly-Si material includes limiting the removal to portions of the doped poly-Si material initially contacting the top and bottom portions of the first electrode and retaining portions contacting the side portions.

10. The method of claim 9, wherein selectively removing the portions of the doped poly-Si material includes applying a self-limiting etching mechanism that limits the removal according to a geometry or one or more dimensions associated with a space occupied by the retaining portions of the doped poly-Si material contacting the side portions, wherein the retaining portions of the doped poly-Si material contacting the side portions corresponds to anchoring liner structures.

11. The method of claim 10, wherein the self-limiting etching mechanism includes tetramethylammonium hydroxide.

12. The method of claim 10, wherein selectively removing the portions of the doped poly-Si material includes applying a first etching mechanism to at least partially remove portions of the doped poly-Si material initially contacting the top and bottom portions of the first electrode.

13. The method of claim 6, wherein depositing a doped poly-Si material includes providing dopants to the semiconductor path through diffusion.

14. The method of claim 13, wherein the doped poly-Si material includes phosphine-doped Si.

15. The method of claim 6, wherein forming the first electrode includes:
depositing an electrode forming layer that corresponds to multiple capacitors, wherein the electrode forming layer includes electrode connecting portions that extend between multiple capacitor housing slots;
depositing a set of protective layers over the electrode forming layer;
shaping the set of protective layers to expose at least the electrode connecting portions;
removing the exposed electrode connecting portions to form the first electrode and isolate the first electrode from other electrodes resulting from the electrode forming layer; and
removing the set of protective layers surrounding the first electrode to expose at least a top surface, a bottom surface, and an inner surface thereof.

16. A semiconductor device, comprising:
a lateral semiconductor path;
a lateral capacitor electrically coupled to the lateral semiconductor path; and
a doped liner disposed between the lateral semiconductor path and the lateral capacitor.

17. The semiconductor device of claim 16, wherein:
the lateral capacitor is a double-sided capacitor having (1) a first electrode with at least an inner portion integral with top and bottom portions that extend laterally away from the lateral semiconductor path, (2) a second electrode positioned between the top and bottom portions of the first electrode, and (3) a high-K layer disposed between the top and first electrodes; and
the doped liner directly contacts and electrically couples to the inner portion of the first electrode.

18. The semiconductor device of claim 17, wherein:
the first electrode of the double-sided capacitor includes side portions that extend vertically between the top and bottom portions and laterally away from the lateral semiconductor path; and
the doped liner includes integral anchoring structures that extend laterally past the inner portion and directly contacting the side portions of the first electrode.

19. The semiconductor device of claim 16, wherein the doped liner includes a planar surface that contacts the lateral semiconductor path.

20. The semiconductor device of claim 16, wherein the doped liner includes a pointed portion that extends into and a past peripheral edge of the lateral semiconductor path.
